(19) United States
(12) Patent Application Publication
(10) Pub. No.: US 2025/0226365 A1
(43) Pub. Date: Jul. 10, 2025

(54) INTEGRATED CIRCUIT DEVICE INCLUDING IMPEDANCE ADAPTER

(71) Applicant: QUALCOMM Incorporated, San Diego, CA (US)

(72) Inventors: Je-Hsiung LAN, San Diego, CA (US); Jonghae KIM, San Diego, CA (US); Ranadeep DUTTA, Del Mar, CA (US)

(21) Appl. No.: 18/406,871

(22) Filed: Jan. 8, 2024

(51) Int. Cl. H01L 25/16; H01L 21/56; H01L 23/00; H01L 23/31; H01L 25/00; H01L 27/06; H01L 27/13

(52) U.S. Cl. CPC H01L 25/16; H01L 21/568; H01L 25/50; H01L 23/3128; H01L 24/08; H01L 24/16; H01L 24/32; H01L 24/73; H01L 24/81; H01L 24/83; H01L 24/92; H01L 2224/08145; H01L 2224/08225; H01L 2224/16145; H01L 2224/16227; H01L 2224/16265; H01L 2224/32225; H01L 2224/73204; H01L 2224/81005; H01L 2224/81815; H01L 2224/83862; H01L 2224/92125; H01L 2924/19042; H01L 2924/19103; H10D 1/20; H10D 84/204; H10D 86/80

(57) ABSTRACT

A packaged integrated circuit device includes a die that includes integrated radio frequency (RF) circuitry. The packaged integrated circuit device also includes a package substrate including metal layers electrically connected to the RF circuitry. The packaged integrated circuit device further includes an impedance adapter electrically connected to the RF circuitry and disposed between the die and the package substrate. The impedance adapter includes a passive component disposed on or in a body of the impedance adapter.

### FIELD

Various features relate to integrated circuit devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power and signal routing issues when multiple impedance matching components are arranged side-by-side within the small form factor.

### SUMMARY

Various features relate to integrated circuit devices.

One example provides a packaged integrated circuit device that includes a die including integrated radio frequency (RF) circuitry. The packaged integrated circuit device also includes a package substrate including metal layers electrically connected to the RF circuitry. The packaged integrated circuit device further includes an impedance adapter electrically connected to the RF circuitry and disposed between the die and the package substrate. The impedance adapter includes a passive component disposed on or in a body of the impedance adapter.

Another example provides a method that includes forming a package substrate including metal layers. The method also includes coupling an impedance adapter to the package substrate. The impedance adapter includes a passive component disposed in or on a body of the impedance adapter. The method further includes electrically connecting a die including integrated radio frequency (RF) circuitry to the impedance adapter on a side of the impedance adapter opposite the package substrate. The method also includes electrically connecting the die to the metal layers through one or more conductors adjacent to the impedance adapter.

Another example provides a packaged integrated circuit device that includes a die including integrated radio frequency (RF) circuitry. The packaged integrated circuit device also includes a package substrate including metal layers electrically connected to the RF circuitry. The packaged integrated circuit device further includes a first impedance adapter electrically connected to the RF circuitry and disposed between the die and the package substrate. The packaged integrated circuit device also includes a second impedance adapter electrically connected to the RF circuitry and disposed between the die and the package substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a block diagram of a low noise amplifier (LNA) power amplifier filter (LPAF) module and a cross-sectional profile view of an exemplary integrated circuit (IC) device that includes an impedance adapter (IA).

FIG. 2A illustrates a cross-sectional profile view of an exemplary IC device that includes an IA.

FIG. 2B illustrates a cross-sectional profile view of an exemplary IC device that includes an IA.

FIG. 3 illustrates a cross-sectional profile view of an exemplary IA that can be included in an IC device.

FIG. 4 illustrates a cross-sectional profile view of an exemplary IA that can be included in an IC device.

FIG. 5 illustrates a cross-sectional profile view of an exemplary varactor diode of the IA of FIG. 4.

FIG. 6 illustrates a cross-sectional profile view of an exemplary IC device that includes an IA.

FIG. 7 illustrates a cross-sectional profile view of an exemplary IA that can be included in the IC device of FIG. 6.

FIG. 8 illustrates a cross-sectional profile view of an exemplary IC device that includes an IA.

FIG. 9 illustrates a cross-sectional profile view of an exemplary IC device that includes an IA.

FIG. 10 illustrates a block diagram of an exemplary IC device that includes a wide band LPAF module and a cross-sectional profile view of the exemplary IC device.

FIG. 11A illustrates Stages of an exemplary sequence for fabricating an exemplary IC device that includes an IA.

FIG. 11B illustrates Stages of the exemplary sequence for fabricating the exemplary IC device that includes the IA.

FIG. 11C illustrates Stages of the exemplary sequence for fabricating the exemplary IC device that includes the IA.

FIG. 11D illustrates Stages of the exemplary sequence for fabricating the exemplary IC device that includes the IA.

FIG. 11E illustrates Stages of the exemplary sequence for fabricating the exemplary IC device that includes the IA.

FIG. 12 illustrates an exemplary flow diagram of a method for fabricating an exemplary IC device that includes an IA.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Impedance matching components that are side-by-side on a package substrate are susceptible to performance issues, such as large insertion loss through the package substrate and large capacitance and inductance variation. The side-by-side components are also not cost-effective or compact. Various aspects of the present disclosure provide an IC device arranged to provide an impedance adapter that is disposed between a die and a package substrate, resulting in improved performance and compact form factor.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Impedance matching in integrated circuit (IC) devices enables efficient power transfer and signal integrity between different components. For example, a radio frequency (RF) circuit can include a low-noise amplifier (LNA) power amplifier (PA) and filter (LPAF) module with impedance matching. The LPAF module is often used in wireless communication systems to amplify weak signals, filter unwanted frequencies, and match impedances for efficient power transfer. Components of the LPAF module side-by-side on a package substrate are susceptible to performance issues, such as large insertion loss through the package substrate and large capacitance and inductance variation. The side-by-side components are also not cost-effective or compact.

Aspects of the present disclosure are directed to an IC device that includes at least one impedance adapter that is disposed between a die and a package substrate. The die includes integrated RF circuitry. In some examples, the IC device includes conductive vias through the impedance adapter that are electrically connected to the RF circuitry and to metal layers of the package substrate, resulting in improved performance and compact form factor.

### Exemplary IC Devices Including Impedance Adapter

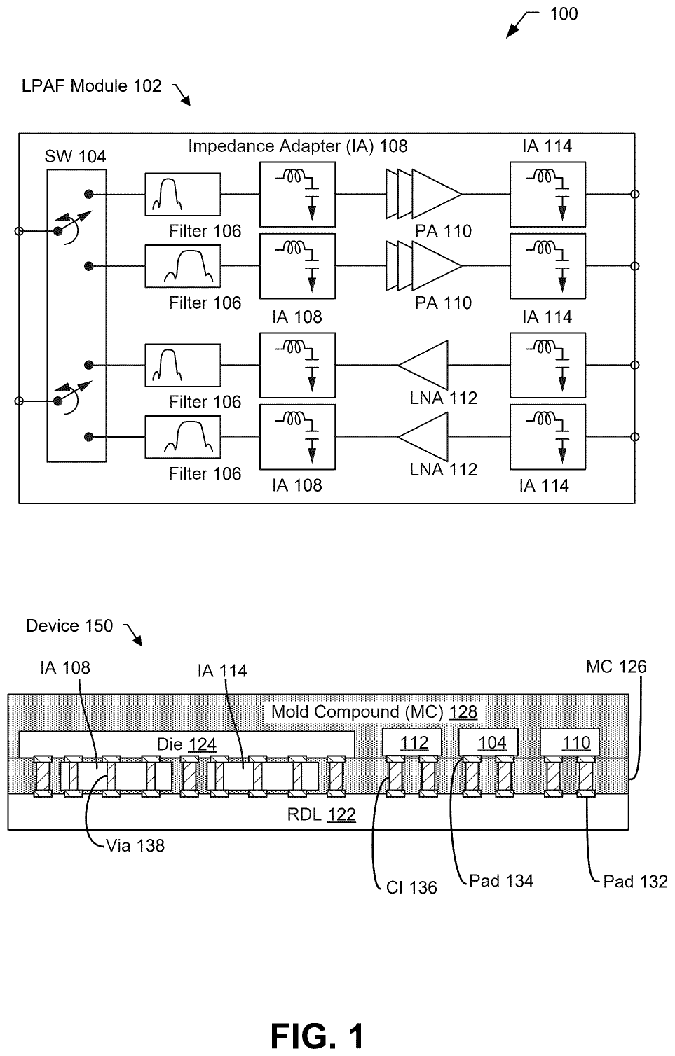

FIG. 1 illustrates a block diagram 100 of a low noise amplifier (LNA) power amplifier filter (LPAF) module 102 and a cross-sectional profile view of an exemplary integrated circuit (IC) device 150 that includes an impedance adapter (IA) 108 and an IA 114.

The LPAF module 102 includes one or more low-noise amplifiers 112, one or more power amplifiers (PAs) 110, and one or more filters 106. The LPAF module 102 also includes one or more impedance adapters 108 and one or more impedance adapters 114 to perform impedance matching between various components of the LPAF module 102.

In an example, the LPAF module 102 includes one or more switches 104, coupled via the one or more filters 106, to the one or more impedance adapters 108. A first subset of the impedance adapters 108 is coupled via the one or more power amplifiers 110 to one or more first impedance adapters 114. For example, an impedance adapter 108 adapts (e.g., matches) an output impedance of a filter 106 to an input impedance of a power amplifier 110.

One or more second impedance adapters 114 are coupled via the one or more low-noise amplifiers 112 to a second subset of the impedance adapters 108. For example, an impedance adapter 108 adapts (e.g., matches) an output impedance of a low-noise amplifier 112 to an input impedance of a filter 106. In a particular embodiment, the power amplifier(s) 110 are included in a transmit path of a transceiver and the LNAs 112 are included in a receive path of the transceiver. In a particular aspect, the device 150 includes the low-noise amplifier(s) 112, the switch(es) 104, and the power amplifier(s) 110 disposed adjacent to a die 124. In a particular aspect, the die 124 includes a complementary metal oxide semiconductor (CMOS) radio frequency (RF) die.

An impedance adapter includes a passive component (e.g., one or more inductors) disposed on or in a body of the impedance adapter. For example, the passive component can include at least one two-dimensional (2D) inductor disposed on a surface of the body of the impedance adapter. As another example, the passive component can include a three-dimensional (3D) inductor including interconnected through vias defining a solenoid, the through vias extending through the body of the impedance adapter. In a particular embodiment, the impedance adapter 108 includes a varactor (e.g., high tuning radio (HTR) varactor) and the impedance adapter 114 includes a metal-insulator-metal (MIM) capacitor (e.g., high quality factor (HQ) high accuracy (HA) MIM capacitor). In a particular embodiment, the impedance adapter 108 includes a hetero-integrated (HI) matching component and the impedance adapter 114 is a matching component. In a particular embodiment, the impedance adapter 108 includes a first MIM capacitor (e.g., HQ HA MIM capacitor) and the impedance adapter 114 includes a second MIM capacitor (e.g., known good dies (KGD) MIM capacitor). In some aspects, an impedance adapter can also include one or more active components, such as at least one of an amplifier, a filter, a power amplifier, or a low noise amplifier.

The device 150 includes the impedance adapter(s) 108 and the impedance adapter(s) 114 disposed between a die 124 and a redistribution layer (RDL) 122. The device 150 includes a first set of conductive vias 138 that extend through the impedance adapter 108, and a second set of conductive vias 138 that extend through the impedance adapter 114. In some embodiments, the first set of conductive via(s) 138 pass through a passive component of the impedance adapter 108, the second set of conductive via(s) 138 pass through a passive component of the impedance adapter 114, or both.

The device 150 includes pads 132 (e.g., landing pads) and pads 134 (e.g., landing pads). The pads 132 are disposed in or on the RDL 122. The conductive vias 138 extend from a first subset of pads 134 to a first subset of pads 132. The device 150 also includes a plurality of conductive interconnects (CIs) 136 that extend from a second subset of the pads 134 through a mold compound (MC) 126 to a second subset of the pads 132.

In a particular aspect, each of the die 124, a low-noise amplifier 112, a switch 104, or a power amplifier 110 of the device 150 is electrically connected through one or more first conductive paths to the RDL 122. A first conductive path includes a pad 134, a conductive interconnect 136, and a pad 132. For example, the conductive interconnect(s) 136 are electrically connected to circuitry of the die 124 and the RDL 122. The die 124 is also electrically connected through one or more second conductive paths to the RDL 122. A second conductive path includes a pad 134, a via 138, and a pad 132. For example, the via(s) 138 are electrically connected to circuitry of the die 124 and the RDL 122.

In a particular aspect, the impedance adapter(s) 108 and the impedance adapter(s) 114 are electrically connected to circuitry of the die 124. For example, the die 124 includes integrated RF circuitry that is electrically connected via a first subset of the pads 134 to the impedance adapter(s) 108 and via a second subset of the pads 134 to the impedance adapter(s) 114.

The mold compound 126 at least partially encapsulates the pad(s) 132, the conductive interconnect(s) 136, the pad(s) 134, the impedance adapter(s) 108, the impedance adapter(s) 114, or a combination thereof. A mold compound 128 at least partially encapsulates the die 124, the low-noise amplifier(s) 112, the switch(es) 104, the power amplifier(s) 110, or a combination thereof. In a particular embodiment, the pad(s) 134 include a first conductive material, the conductive interconnect(s) 136 include a second conductive material, the pad(s) 132 include a third conductive material, the vias 138 include a fourth conductive material, or a combination thereof. In some aspects, a conductive material can include copper, aluminum, gold, nickel, tin-silver alloy, or a combination thereof.

In a particular embodiment, the conductive interconnect(s) 136 correspond to copper pillars, the via(s) 138 include a metal coated material, and the pad(s) 132 and the pad(s) 134 correspond to metal pads. Pillars, bumps, and pads are used as illustrative examples of shapes of components (e.g., the CI 136, the via 138, the pad 132, and the pad 134) of the device 150. In other examples, one or more components (e.g., the CI 136, the via 138, the pad 132, and the pad 134) of the device 150 can have a different shape, such as a pillar, a pad, a bump, a ball, a trace, etc.

The die 124 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry in and/or over the semiconductor substrate.

The die 124 can include active circuitry, for example, processing logic blocks (e.g., transistor blocks), memory blocks, etc. In some implementations, the die 124 includes input/output (I/O) circuitry, and the first conductive paths, the second conductive paths, or a combination thereof, are connected to the I/O circuitry to provide a data path between the die 124 and another device that is coupled to the RDL 122. As one illustrative example, the other device can include a Dynamic Random-Access Memory (DRAM) chip (or chiplet).

In some implementations, the die 124 is a first chiplet, the low-noise amplifier 112 is a second chiplet, the switch 104 is a third chiplet, the power amplifier 110 is a fourth chiplet, the impedance adapter 108 is a fifth chiplet, and the impedance adapter 114 is a sixth chiplet that are designed to operate in conjunction with each other. Forming the device 150 using chiplets arranged and interconnected as a stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, the die 124 of the device 150 can include components (e.g., interconnects, transistors, etc.) that have a first minimum size, and the low-noise amplifier 112 of the device 150 can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an IC (e.g., the device 150), resulting in overall savings. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

A technical advantage of positioning the impedance adapter(s) 108 and the impedance adapter(s) 114 under the die 124 in the mold compound 126 is that this reduces insertion loss. For example, insertion loss associated with the mold compound 126 is lower than insertion loss through a package substrate. Technical advantages of positioning the impedance adapter(s) 108 and the impedance adapter(s) 114 under the die 124 can include improved performance (e.g., reduced capacitor variance, and more efficient inductance) and reduced size as compared to having components of the LPAF module 102 side-by-side.

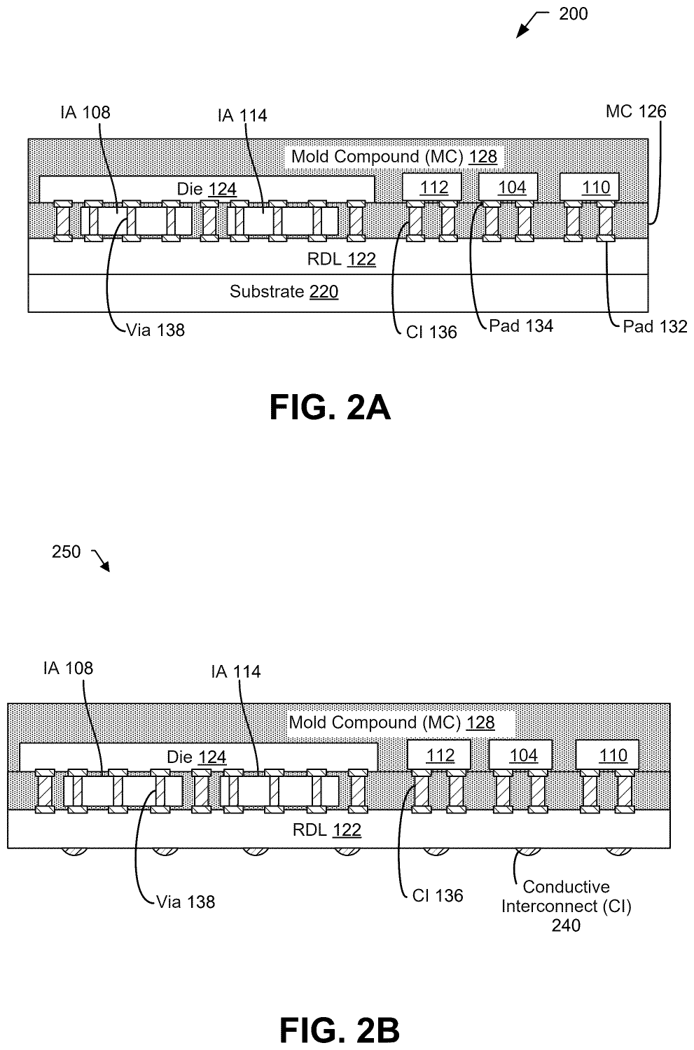

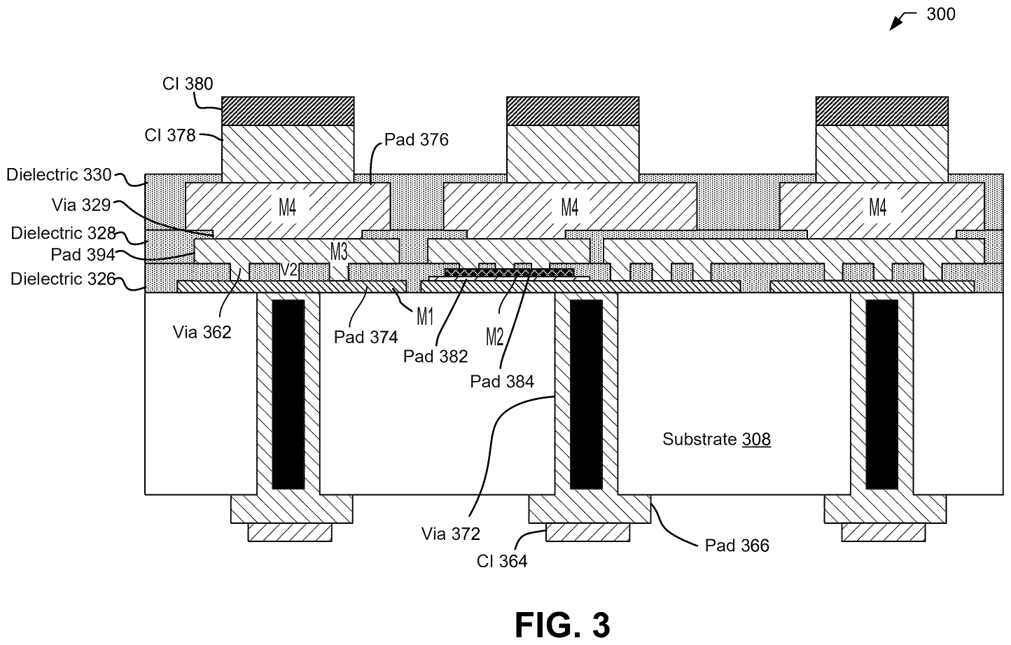

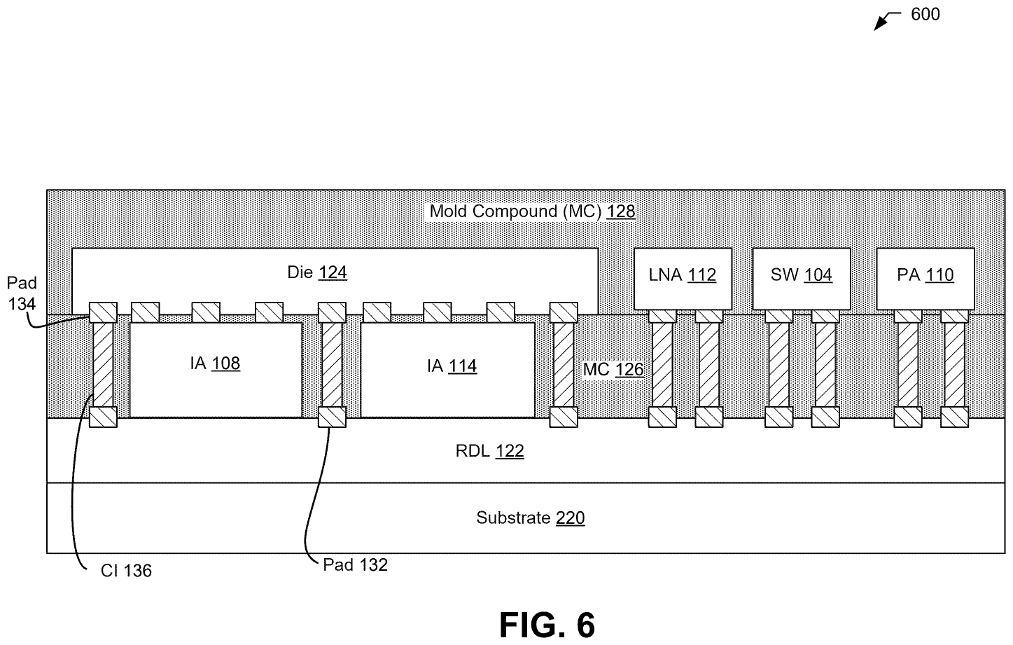

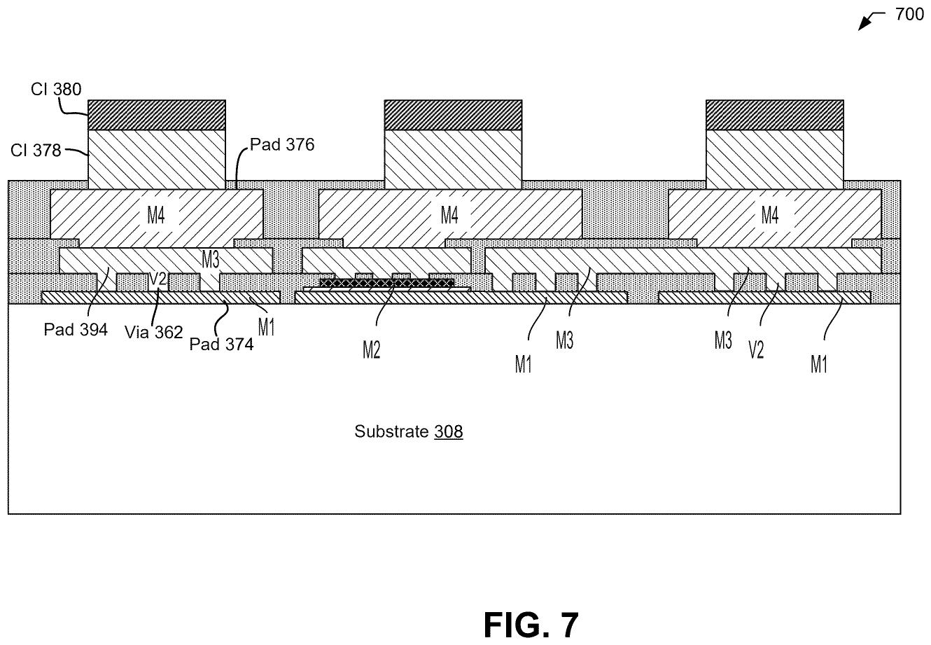

In a particular aspect, the device 150 includes a HI RF matching component structure, which integrates a RF matching component (e.g., the impedance adapter 108) with copper pillars (e.g., the conductive interconnects 136) built on a substrate with copper RDL layers (e.g., the RDL 122) for 5G RF frontend applications, as further described with reference to FIG. 2A. The impedance adapter 108 (e.g., the RF HI matching component) can include an embedded device with one-sided bumps (e.g., the pads 134 on the impedance adapter 108), as further described with reference to FIGS. 6-7, or two-sided bumps (e.g., the pads 134 and the pads 132 on the impedance adapter 108), as described with reference to FIGS. 1 and 3. The impedance adapter 108 can include integrated passive devices (IPDs), active devices, or a combination thereof. In a particular embodiment, the impedance adapter 108 corresponds to a low-loss IPD (e.g., an HQ inductor) and the impedance adapter 114 corresponds to a high-accuracy MIM capacitor attached under the die 124 (e.g., a RF-CMOS transmit/receive chipset).

In a particular aspect, the impedance adapter 108 (e.g., a HI matching component device) with a compact and low loss IPD filter can replace surface mount technology (SMT) components. In a particular aspect, the device 150 with the impedance adapter 108 (e.g., a high performance HI matching component device) with active components and passive components is compatible for 5G and WiFi6 radio frequency front end (RFFE) applications. In a particular aspect, the device 150 can include the impedance adapter 108 (e.g., a HQ HA MIM) for performance enhancement, and the impedance adapter 114 (e.g., KGD) for yield improvement.

FIG. 2A illustrates a cross-sectional profile view of a device 200 that includes impedance adapter(s) 108 and impedance adapter(s) 114, and FIG. 2B illustrates a cross-sectional profile view of a device 250 that includes impedance adapter(s) 108 and impedance adapter(s) 114.

Each of the device 200 of FIG. 2A and the device 250 of FIG. 2B include many of the same components and features as are described above with reference to the device 150 of FIG. 1. Such components and features are physically and operationally the same as described above with reference to FIG. 1 and are labeled in FIGS. 2A and 2B using the same reference numbers. In some implementations, the device 200, the device 250, or both, include all of the same features and components as the device 150 of FIG. 1; however, some components and features illustrated in FIG. 1 have been omitted from (or are not labeled with reference numbers in) FIGS. 2A and 2B for simplicity of illustration and to highlight differences between the device 150 and the devices 200 and 250. Omission of such features and reference numbers should not be understood as limiting the features and components of FIGS. 2A and 2B to only those specifically called out below.

In the example illustrated in FIG. 2A, the device 150 is attached to a substrate 220 to form the device 200. To illustrate, the RDL 122 is disposed in or on the substrate 220. In a particular aspect, the substrate 220 corresponds to a package substrate, and the device 200 corresponds to a packaged IC device. The RDL 122 is provided as an illustrative example of metal layers disposed in or on the substrate 220. Additionally or alternatively, other types of metal layers (e.g., metal traces) can be disposed in or on the substrate 220.

The metal layers (e.g., the RDL 122, metal traces, or a combination thereof) of the substrate 220 are electrically connected to the die 124. For example, the metal layers are electrically connected via first conductive paths through the conductive interconnects 136, via second conductive paths through the vias 138, or both, to circuitry of the die 124.

In a particular aspect, the metal layers (e.g., the RDL 122, metal traces, or a combination thereof) of the substrate 220 are electrically connected to at least one of the low-noise amplifier(s) 112, the switch(es) 104, or the power amplifier(s) 110. For example, the metal layers (e.g., the RDL 122, metal traces, or a combination thereof) of the substrate 220 are electrically connected via conductive paths through the conductive interconnects 136 to at least one of the low-noise amplifier(s) 112, the switch(es) 104, or the power amplifier(s) 110.

In the example illustrated in FIG. 2B, one or more conductive interconnects 240 are attached to the device 150 to form the device 250. For example, the conductive interconnect(s) 240 can include bumps, balls, pads, pillars, or other types of conductive interconnects. In a particular aspect, the device 250 corresponds to a packaged IC device. In a particular aspect, the RDL 122 is electrically connected to one or more other devices through the conductive interconnect(s) 240.

In a particular aspect, the conductive interconnect(s) 240 are electrically connected to the die 124. For example, the conductive interconnect(s) 240 are electrically connected via first conductive paths through the RDL 122 and the conductive interconnects 136, via second conductive paths through the RDL 122 and the vias 138, or both, to circuitry of the die 124.

In a particular aspect, the conductive interconnect(s) 240 are electrically connected to at least one of the low-noise amplifier(s) 112, the switch(es) 104, or the power amplifier(s) 110. For example, the conductive interconnect(s) 240 are electrically connected via conductive paths through the RDL 122 and the conductive interconnects 136 to at least one of the low-noise amplifier(s) 112, the switch(es) 104, or the power amplifier(s) 110.

FIG. 3 illustrates a cross-sectional profile view of an exemplary impedance adapter 300 that can be included in an IC device. In a particular example, the impedance adapter 300 corresponds to the impedance adapter 108 of FIG. 1. In a particular example, the impedance adapter 300 corresponds to the impedance adapter 114 of FIG. 1.

The impedance adapter 300 includes a substrate 308. In a particular aspect, the substrate 308 includes gallium arsenide (GaAs), alumina, glass, mold compound, high resistivity silicon (HRS), or a combination thereof. In a particular aspect, the substrate 308 includes one or more conductive vias 372 that extend from one or more pads 374 on a first surface of the substrate 308 through the substrate 308 to one or more pads 366 on a second surface of the substrate 308 that is opposite the first surface. In a particular aspect, the impedance adapter 300 includes a passive component. For example, the passive component includes a 3D inductor including interconnected through vias (e.g., the conductive via(s) 372) defining a solenoid.

In a particular embodiment, the impedance adapter 300 includes a plurality of metal layers on the substrate 308 that are electrically connected through the via(s) 372 and the pad(s) 366 to conductive interconnect(s) 364. In an example, the impedance adapter 300 includes a first metal layer (M1), a second metal layer (M2), a third metal layer (M3), and a fourth metal layer (M4). The first metal layer is disposed on portions of a first surface of the substrate 308. The second metal layer is disposed on (or electrically connected to) at least a portion of the first metal layer. The third metal layer is disposed on (or electrically connected to) at least a portion of the first metal layer, at least a portion of the second metal layer, or both. The fourth metal layer is disposed on (or electrically connected to) at least a portion of the third metal layer.

In a particular aspect, the first metal layer includes the pad(s) 374. The second metal layer includes a pad 384 electrically connected through a pad 382 to a pad 374. The third metal layer includes one or more pads 394. The pad(s) 394 are electrically connected through via(s) 362 to the pad(s) 374. In a particular aspect, a pad 394 is electrically connected through a plurality of vias 362, the pad 384, and the pad 382 to a pad 374. The fourth metal layer includes one or more pads 376 that are electrically connected through via(s) 329 to the pad(s) 394. In a particular aspect, the first metal layer, the second metal layer, and the pad 382 corresponds to a MIM capacitor, and the fourth metal layer corresponds to a RDL, a 2D inductor, or both.

In a particular aspect, the impedance adapter 300 has two-sided bumps. For example, the impedance adapter 300 includes the conductive interconnect(s) 364 on a first side of the impedance adapter 300 and one or more conductive interconnects 380 on a second side of the impedance adapter 300 that is opposite the first side. The conductive interconnect(s) 380 are electrically connected through the conductive interconnect(s) 378 to the fourth metal layer. For example, a conductive interconnect 380 is electrically connected through a conductive interconnect 378 to a pad 376. Pads, conductive interconnects, and conductive vias include various conductive materials. In some aspects, a conductive material can include copper, aluminum, gold, nickel, tin-silver alloy, or a combination thereof.

One or more dielectric layers are disposed between the metal layers. For example, a dielectric layer 326 is disposed at least partially between the first metal layer (e.g., the pad(s) 374) and the third metal layer (e.g., the pad(s) 384). As another example, a dielectric layer 328 is disposed at least partially between the third metal layer (e.g., the pad(s) 384) and the fourth metal layer (e.g., the pad(s) 376). In a particular aspect, the dielectric layer 326 at least partially encapsulates the first metal layer (e.g., the pad(s) 374), the pad 382, the second metal layer (e.g., the pad(s) 384), the via(s) 362, or a combination thereof. In a particular aspect, the dielectric layer 328 at least partially encapsulates the third metal layer (e.g., the pad(s) 384), the via(s) 329, or a combination thereof. In a particular aspect, a dielectric layer 330 at least partially encapsulates the fourth metal layer (e.g., the pad(s) 376), the conductive interconnect(s) 378, or a combination thereof.

In a particular aspect, the via(s) 138 of FIG. 1 include the via(s) 372, conductive paths between the via(s) 372 and the conductive interconnect(s) 380, or a combination thereof. In a particular aspect, the pad(s) 134 of FIG. 1 that are electrically connected to the via(s) 138 include the conductive interconnect(s) 380, the conductive interconnect(s) 378, the pad(s) 376, or a combination thereof. In a particular aspect, the pad(s) 132 of FIG. 1 that are electrically connected to the via(s) 138 include the conductive interconnect(s) 364, the pad(s) 366, or a combination thereof.

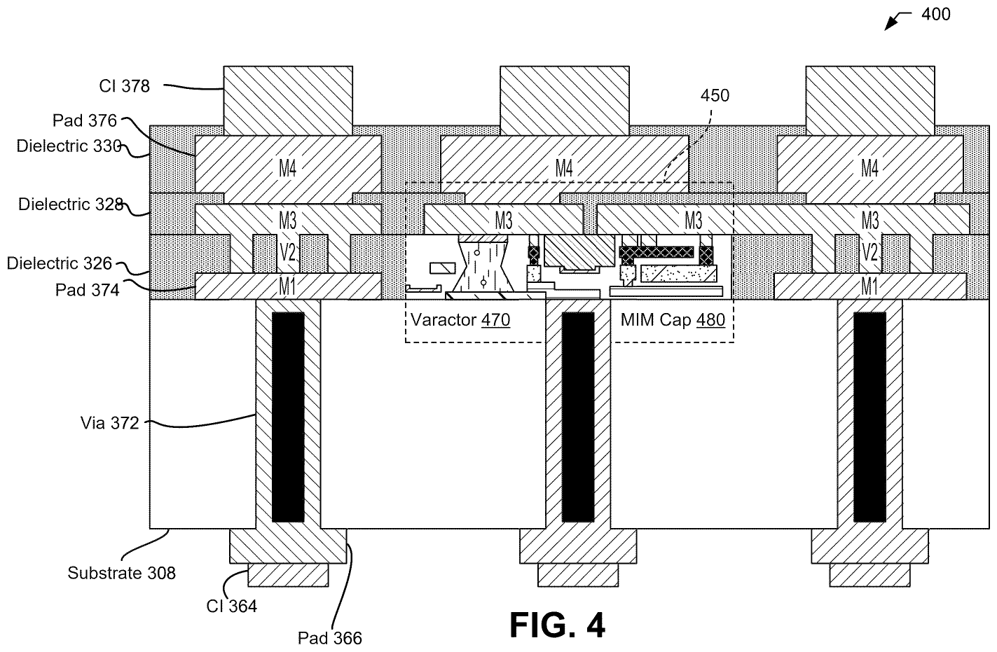

FIG. 4 illustrates a cross-sectional profile view of an exemplary impedance adapter 400 that can be included in an IC device. In a particular example, the impedance adapter 400 corresponds to the impedance adapter 108 of FIG. 1. In a particular example, the impedance adapter 400 corresponds to the impedance adapter 114 of FIG. 1.

The impedance adapter 400 of FIG. 4 includes many of the same components and features as are described above with reference to the impedance adapter 300 of FIG. 3. Such components and features are physically and operationally the same as described above with reference to FIG. 3 and are labeled in FIG. 4 using the same reference numbers. In some implementations, the impedance adapter 400 includes all of the same features and components as the impedance adapter 300 of FIG. 3; however, some components and features illustrated in FIG. 3 have been omitted from (or are not labeled with reference numbers in) FIG. 4 for simplicity of illustration and to highlight differences between the impedance adapter 300 and the impedance adapter 400. Omission of such features and reference numbers should not be understood as limiting the features and components of FIG. 4 to only those specifically called out below.

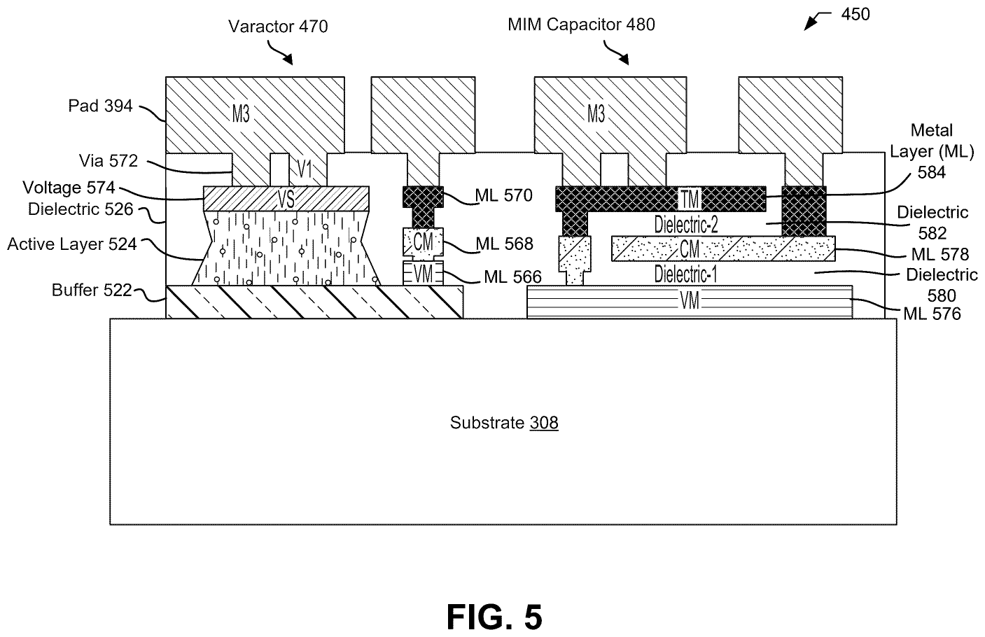

In the example illustrated in FIG. 4, the impedance adapter 400 includes a tunable capacitance structure 450, as further described with reference to FIG. 5. The tunable capacitance structure 450 includes a varactor 470 and a MIM capacitor 480, as further described with reference to FIG. 5. In a particular aspect, the MIM capacitor 480 provides a reliable and constant capacitance value in the absence of voltage control. The varactor 470 exhibits a variable capacitance when voltage across the varactor 470 is changed. The tunable capacitance structure 450 including the varactor 470 and the MIM capacitor 480 has both variable and fixed capacitance components.

In a particular embodiment, the tunable capacitance structure 450 can be used as part of a voltage-controlled tunable filter (e.g., a filter 106 of FIG. 1). The varactor 470 can be used to adjust the filter's center frequency based on applied voltage. The MIM capacitor 480 can provide additional fixed capacitance for stability in the filter's response. A filter including the tunable capacitance structure 450 is provided as an illustrative example, in other examples the tunable capacitance structure 450 can be included in other types of components, such as a voltage controlled oscillator, a frequency modulator, etc.

FIG. 5 illustrates a cross-sectional profile view of the tunable capacitance structure 450. In a particular embodiment, the tunable capacitance structure 450 is included in the impedance adapter 400 of FIG. 4.

In the example illustrated in FIG. 5, the varactor 470 includes a buffer 522 between an active layer 524 and the substrate 308. In a particular embodiment, the buffer 522 includes gallium arsenide. In a particular embodiment, the active layer 524 includes gallium arsenide. Adjusting a voltage (VS) 574 (e.g., a reverse-bias voltage) applied across the active layer 524 can tune a capacitance of the varactor 470. In a particular aspect, the active layer 524 exhibits an abrupt capacitance-voltage characteristic. For example, when the active layer 524 exhibits an abrupt capacitance-voltage characteristic, a change in capacitance of the varactor 470 is inversely proportional to a square root of applied voltage. In an alternative aspect, the active layer 524 exhibits a hyperabrupt capacitance-voltage characteristic. For example, when the active layer 524 the hyperabrupt capacitance-voltage characteristic, the change in capacitance of the varactor 470 is more non-linear as compared to the change in capacitance corresponding to the abrupt capacitance-voltage characteristic. To illustrate, a small change in the VS 574 corresponds to a relatively large change in the capacitance of the varactor 470 when the active layer 524 exhibits an abrupt capacitance-voltage characteristic.

The varactor 470 is electrically connected through one or more vias 572 to one or more pads 394 (e.g., the third metal layer of the impedance adapter 400). In a particular aspect, the buffer 522 is electrically connected through one or more metal layers, such as a metal layer 566 (e.g., a bottom metal layer (VM)), a metal layer 568 (e.g., a center metal layer (CM)), and a metal layer 570 (e.g., a top metal layer (TM)) to one or more pads 394 (e.g., the third metal layer of the impedance adapter 400).

The MIM capacitor 480 includes a plurality of metal layers separated by insulator layers. For example, the MIM capacitor 480 includes a metal layer 576 (e.g., a VM), a metal layer 578 (e.g., a CM), and a metal layer 584 (e.g., a TM). The MIM capacitor 480 includes a dielectric 580 between at least a portion of the metal layer 576 and at least a portion of the metal layer 578, and a dielectric 582 between at least a portion of the metal layer 578 and at least a portion of the metal layer 584. The MIM capacitor 480 including three metal layers at least partially separated by insulator layers is provided as an illustrative example, in other examples the MIM capacitor 480 can include fewer than three or more than three metal layers at least partially separated by insulator layers. The metal layer 584 is electrically connected to one or more pads 394 (e.g., the third metal layer of the impedance adapter 400). The tunable capacitance structure 450 includes a dielectric 526 that at least partially encapsulates the varactor 470, the MIM capacitor 480, or both.

FIG. 6 illustrates a cross-sectional profile view of a device 600 that includes impedance adapter(s) 108 and impedance adapter(s) 114. The device 600 of FIG. 6 includes many of the same components and features as are described above with reference to the device 200 of FIGS. 1 and 2A. Such components and features are physically and operationally the same as described above with reference to FIGS. 1 and 2A and are labeled in FIG. 6 using the same reference numbers. In some implementations, the device 600 includes all of the same features and components as the device 150 of FIG. 1, the device 200 of FIG. 2A, or both; however, some components and features illustrated in FIG. 1 or 2A have been omitted from (or are not labeled with reference numbers in) FIG. 6 for simplicity of illustration and to highlight differences between the devices 150 and 200 and the device 600. Omission of such features and reference numbers should not be understood as limiting the features and components of FIG. 6 to only those specifically called out below.

In the example illustrated in FIG. 6, the device 600 includes the impedance adapter 108 and the impedance adapters 114 having one-sided bumps. In contrast to the impedance adapters 108 and 114 of FIGS. 1 and 2A, the impedance adapter 108 and the impedance adapter 114 of the device 600 do not include the pad(s) 132 on a first side of the impedance adapter 108 or the impedance adapter 114. The impedance adapter 108 and the impedance adapter 114 include one or more pad(s) 134 on a second side of the impedance adapter 108 and the impedance adapter 114 that are electrically connected to circuitry of the die 124.

FIG. 7 illustrates a cross-sectional profile view of an exemplary impedance adapter 700 that can be included in an IC device. In a particular example, the impedance adapter 700 corresponds to an impedance adapter 108 of FIG. 6. In a particular example, the impedance adapter 700 corresponds to an impedance adapter 114 of FIG. 6.

The impedance adapter 700 of FIG. 7 includes many of the same components and features as are described above with reference to the impedance adapter 300 of FIG. 3. Such components and features are physically and operationally the same as described above with reference to FIG. 3 and are labeled in FIG. 7 using the same reference numbers. In some implementations, the impedance adapter 700 includes some of the same features and components as the impedance adapter 300 of FIG. 3; however, some components and features illustrated in FIG. 3 have been omitted from (or are not labeled with reference numbers in) FIG. 7 for simplicity of illustration and to highlight differences between the impedance adapter 300 and the impedance adapter 700. Omission of such features and reference numbers should not be understood as limiting the features and components of FIG. 7 to only those specifically called out below.

In the example illustrated in FIG. 7, the impedance adapter 700 has one-sided bumps. In contrast to the impedance adapter 300 of FIG. 3, the impedance adapter 700 does not include the conductive interconnect(s) 364 or the pad(s) 366 on a first side of the impedance adapter 700 and does not include the via(s) 372 extending through the substrate 308. The impedance adapter 700 includes the conductive interconnect(s) 380, the conductive interconnect(s) 378, and the pad(s) 376 corresponding to the one or more pad(s) 134 on a second side of the impedance adapter 700.

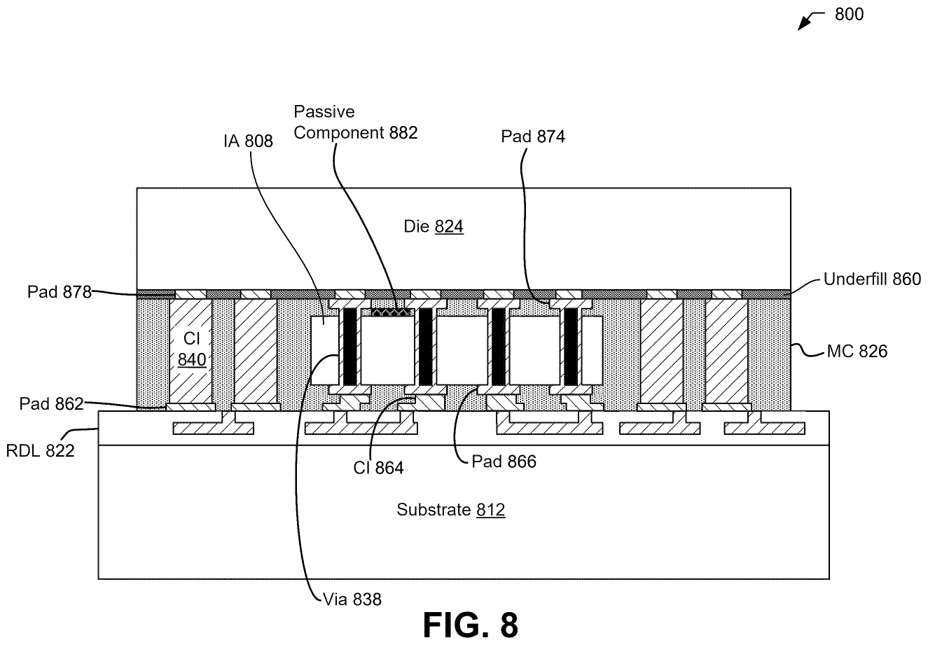

FIG. 8 illustrates a cross-sectional profile view of a device 800 that includes an impedance adapter 808. In a particular aspect, the impedance adapter 808 corresponds to the impedance adapter 108, the impedance adapter 114 of FIG. 1, the impedance adapter 300 of FIG. 3, or a combination thereof. Although the impedance adapter 808 is illustrated as having two-sided bumps, in some embodiments, the impedance adapter 808 has one-sided bumps. For example, the impedance adapter 808 corresponds to the impedance adapter 700 of FIG. 7.

The device 800 includes the impedance adapter 808 disposed between a die 824 and a RDL 822. For example, the RDL 822 includes metal traces electrically connected to various components of the device 800. In a particular embodiment, the RDL 822 is disposed on a substrate 812 (e.g., a package substrate). In a particular aspect, the die 824 includes a CMOS RF die. In a particular aspect, the die 824 includes circuitry associated with a transceiver.

The impedance adapter 808 includes a passive component 882 (e.g., one or more inductors) disposed on or in a body of the impedance adapter 808. For example, the passive component 882 can include at least one 2D inductor disposed on a surface of the body of the impedance adapter 808. As another example, the passive component 882 can include a 3D inductor including interconnected through vias defining a solenoid, the through vias extending through the body of the impedance adapter 808. In a particular embodiment, the passive component 882 includes a varactor, a MIM capacitor, or both. In a particular embodiment, the impedance adapter 808 includes an HI matching component. In some aspects, the impedance adapter 808 can also include one or more active components, such as at least one of an amplifier, a filter, a power amplifier, or a low noise amplifier.

The device 800 includes one or more conductive vias 838 that extend through the impedance adapter 808. In some embodiments, the passive component 882 of the impedance adapter 808 includes the conductive via(s) 838. For example, the conductive via(s) 838 pass through the passive component 882.

The device 800 includes pads 862 (e.g., landing pads) and pads 878 (e.g., landing pads). The pads 862 are disposed in or on the RDL 122. The pads 878 are disposed in or on the die 824. The device 800 includes conductive interconnect(s) 840 extending from a first subset of the pads 862 to a first subset of the pads 878. For example, the RDL 122 is electrically connected via the conductive interconnect(s) 840 to circuitry of the die 824.

The device 800 includes one or more pads 874 between the via(s) 838 and a second subset of the pads 878. The device 800 also includes one or more pads 866 electrically connected via one or more conductive interconnects 864 to a second subset of the pads 862. For example, the RDL 122 is electrically connected through the via(s) 838 to circuitry of the die 824.

In a particular aspect, the impedance adapter 808 is electrically connected to circuitry of the die 824. For example, the die 824 includes integrated RF circuitry that is electrically connected via the second subset of the pads 878, the pad(s) 874, and the via(s) 838 to the impedance adapter 808.

The mold compound 826 at least partially encapsulates the RDL 822, the pad(s) 862, the conductive interconnect(s) 840, the pad(s) 878, the conductive interconnect(s) 864, the pad(s) 866, the impedance adapter 808, the pad(s) 874, the passive component 882, or a combination thereof. In a particular aspect, the device 800 includes an underfill 860 between the mold compound 826 and the die 824.

In a particular embodiment, the pad(s) 862, the conductive interconnect(s) 840, the pad(s) 878, the conductive interconnect(s) 864, the pad(s) 866, the pad(s) 874, or a combination thereof, include various conductive materials. In some aspects, a conductive material can include copper, aluminum, gold, nickel, tin-silver alloy, or a combination thereof.

In a particular embodiment, the conductive interconnect(s) 840 correspond to copper pillars, the via(s) 838 include a metal coated material, and the pad(s) 862, the pad(s) 866, the pad(s) 874, and the pad(s) 878 correspond to metal pads. Pillars, bumps, and pads are used as illustrative examples of shapes of components (e.g., the CI 840, the via 838, the pad 862, the CI 864, the pad 866, the pad 874, and the pad 878) of the device 800. In other examples, one or more components (e.g., the CI 840, the via 838, the pad 862, the CI 864, the pad 866, the pad 874, and the pad 878) of the device 800 can have a different shape, such as a pillar, a pad, a bump, a ball, a trace, etc. In a particular aspect, the underfill 860 includes an epoxy.

The die 824 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry in and/or over the semiconductor substrate.

The die 824 can include active circuitry, for example, processing logic blocks (e.g., transistor blocks), memory blocks, etc. In some implementations, the die 824 includes input/output (I/O) circuitry, and the conductive interconnect(s) 840, the via(s) 838, or both, are connected to the I/O circuitry to provide a data path between the die 824 and another device that is coupled to the RDL 122. As one illustrative example, the other device can include a DRAM chip (or chiplet).

In some implementations, the die 824 is a first chiplet and the impedance adapter 808 is a second chiplet that is designed to operate in conjunction with the first chiplet. Forming the device 800 using chiplets arranged and interconnected as a stacked IC can provide various benefits as compared to providing the same functional circuitry in one monolithic chip.

A technical advantage of positioning the impedance adapter 808 under the die 824 in the mold compound 826 is that this reduces insertion loss. For example, insertion loss associated with the mold compound 826 is lower than insertion loss through a package substrate. Technical advantages of positioning the impedance adapter 808 under the die 824 can include improved performance (e.g., reduced capacitor variance, and more efficient inductance) and reduced size as compared to having components side-by-side.

In a particular aspect, the device 800 includes a hetero-integrated (HI) RF matching component structure, which integrates a RF matching component (e.g., the impedance adapter 808) with copper pillars (e.g., the conductive interconnect(s) 840) built on the substrate 812 with copper RDL layers (e.g., the RDL 122) for 5G RF frontend application. The impedance adapter 808 (e.g., the RF HI matching component) can include an embedded device with one-sided bumps (e.g., the pads 874 on the impedance adapter 808), or two-sided bumps (e.g., the pads 874 and the pads 866 on the impedance adapter 808). The impedance adapter 808 can include integrated passive devices (e.g., the passive component 882), active devices, or a combination thereof.

In a particular aspect, the impedance adapter 808 (e.g., a HI matching component device) with a compact and low loss IPD filter can replace SMT components. In a particular aspect, the device 800 with the impedance adapter 808 (e.g., a high performance HI matching component device) with active components and passive components is compatible for 5G and WiFi6 RFFE application.

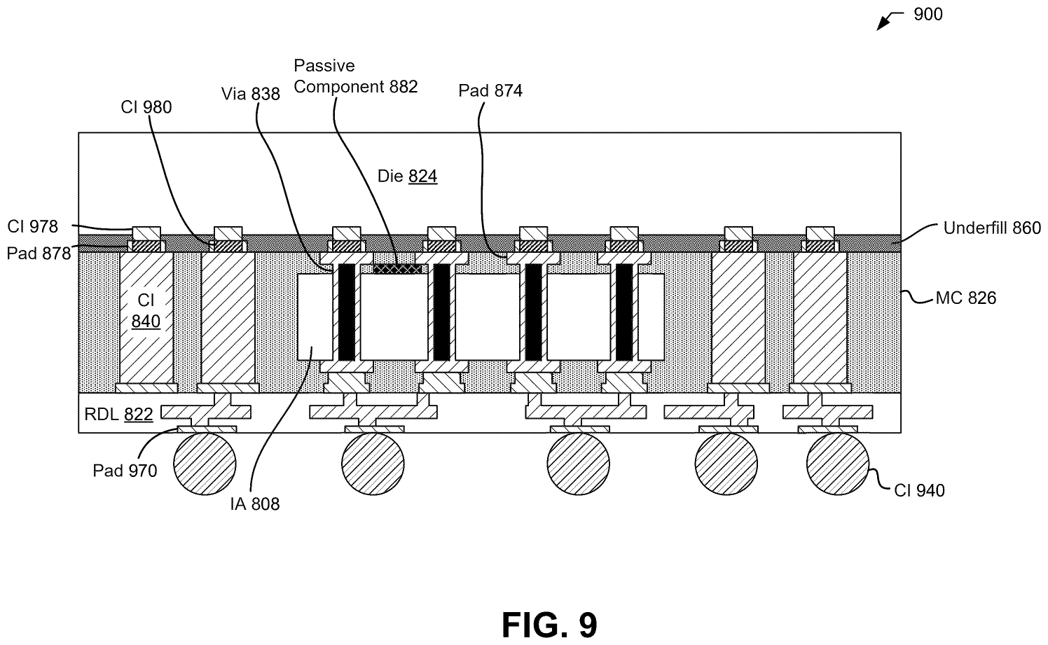

FIG. 9 illustrates a cross-sectional profile view of a device 900 that includes one or more impedance adapters 808. The device 900 of FIG. 9 includes many of the same components and features as are described above with reference to the device 800 of FIG. 8. Such components and features are physically and operationally the same as described above with reference to FIG. 8 and are labeled in FIG. 9 using the same reference numbers. In some implementations, the device 900 includes some of the same features and components as the device 800 of FIG. 8; however, some components and features illustrated in FIG. 8 have been omitted from (or are not labeled with reference numbers in) FIG. 9 for simplicity of illustration and to highlight differences between the device 800 and the device 900. Omission of such features and reference numbers should not be understood as limiting the features and components of FIG. 9 to only those specifically called out below.

In the example illustrated in FIG. 9, the device 900 includes a plurality of conductive interconnect(s) 940 (e.g., solder balls) disposed on a first side of the RDL 822 with the impedance adapter 808 disposed on a second side of the RDL 822 that is opposite the first side. For example, the device 900 includes one or more pads 970 disposed between and electrically connecting the RDL 822 and the conductive interconnect(s) 940. In a particular embodiment, the conductive interconnect(s) 940 (e.g., solder bumps) are disposed on a first side of a substrate (e.g., a package substrate), and the RDL 822 is disposed on a second side of the substrate that is opposite the first side. To illustrate, the RDL 822 is disposed between the impedance adapter 808 and the substrate.

In a particular embodiment, one or more conductive interconnect(s) 978 are disposed in or on the die 824 and are electrically connected to respective conductive interconnect(s) 980 that extend through the pad(s) 878. In a particular example, a first subset of the conductive interconnect(s) 980 are electrically connected to the conductive interconnect(s) 840 and a second subset of the conductive interconnect(s) 980 are electrically connected to the pad(s) 874. The underfill 860 at least partially encapsulates the conductive interconnect(s) 978, the pad(s) 878, or a combination thereof.

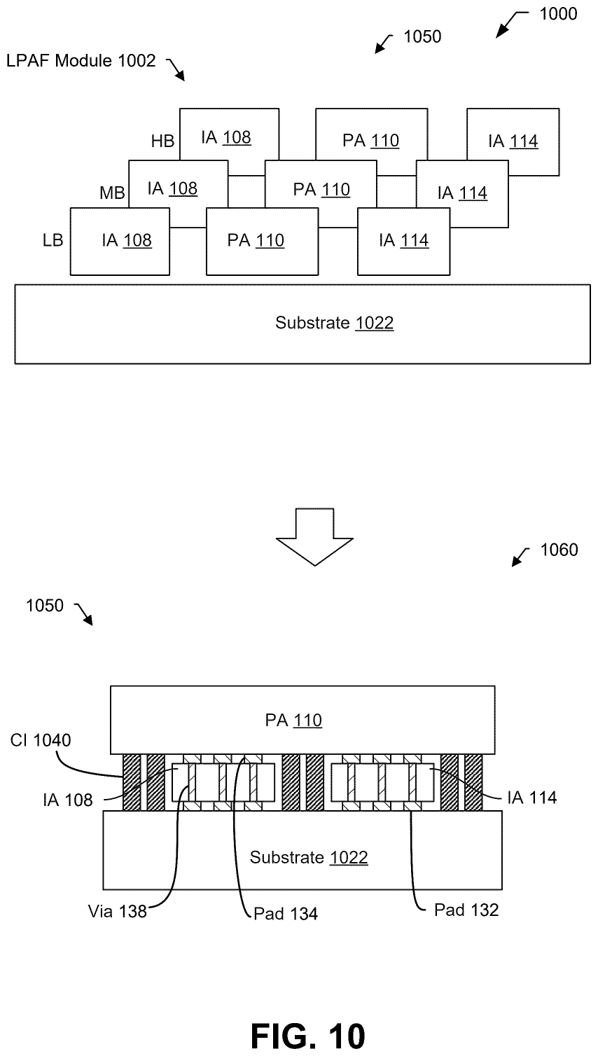

FIG. 10 illustrates a block diagram 1000 of a device 1050 including a wide band LPAF module 1002 and a cross-sectional profile view 1060 of the device 1050. The wide band LPAF module 1002 includes one or more impedance adapters 108 and one or more impedance adapters 114.

The device 1050 includes the wide band LPAF module 1002 disposed on a substrate 1022 (e.g., a package substrate). The wide band LPAF module 1002 includes first impedance adapter(s) 108, first power amplifier(s) 110, and first impedance adapter(s) 114 associated with a first frequency band (e.g., low band (LB)) having a first start frequency and a first end frequency. The wide band LPAF module 1002 includes second impedance adapter(s) 108, second power amplifier(s) 110, and second impedance adapter(s) 114 associated with a second frequency band (e.g., medium band (MB)) having a second start frequency and a second end frequency. The wide band LPAF module 1002 includes third impedance adapter(s) 108, third power amplifier(s) 110, and third impedance adapter(s) 114 associated with a third frequency band (e.g., high band (HB)) having a third start frequency and a third end frequency. The second start frequency is greater than the first start frequency, and the third start frequency is greater than the second start frequency.

As illustrated in the view 1060, the device 1050 includes one or more conductive interconnect(s) 1040 that extend from the substrate 1022 to a power amplifier 110. The device 1050 includes impedance adapter(s) 108 and impedance adapter(s) 114 between the power amplifier 110 and the substrate 1022. In a particular aspect, the device 1050 includes one or more via(s) 138 electrically connecting the power amplifier 110 to the substrate 1022. In an example, a via 138 extends from a pad 132 on the substrate 1022 to a pad 134 on the power amplifier 110.

In a particular implementation, first conductive paths from the substrate 1022 through a first subset of the pads 132, via(s) 138 that extend through the impedance adapter 108, a first subset of the pads 134, to the power amplifier 110 correspond to an input path to the power amplifier 110. For example, the impedance adapter 108 adjusts impedance based on an input impedance of the power amplifier 110. In a particular implementation, second conductive paths from the power amplifier 110 through a second subset of the pads 134, via(s) 138 that extend through the impedance adapter 114, a second subset of the pads 132, to the substrate 1022 correspond to an output path of the power amplifier 110. For example, the impedance adapter 114 adjusts impedance based on an output impedance of the power amplifier 110.

In a particular aspect, a first set of the power amplifier 110, the impedance adapter 108, and the impedance adapter 114 illustrated in the view 1060 are associated with the LB. The device 1050 includes a second set of the power amplifier 110, the impedance adapter 108, and the impedance adapter 114 associated with MB, and a third set of the power amplifier 110, the impedance adapter 108, and the impedance adapter 114 associated with HB. The wide band LPAF module 1002 corresponding to three frequency bands is provided as an illustrative example, in other examples the wide band LPAF module 1002 can include fewer than three or more than three frequency bands.

### Exemplary Sequence for Fabricating an IC Device Including Impedance Adapter

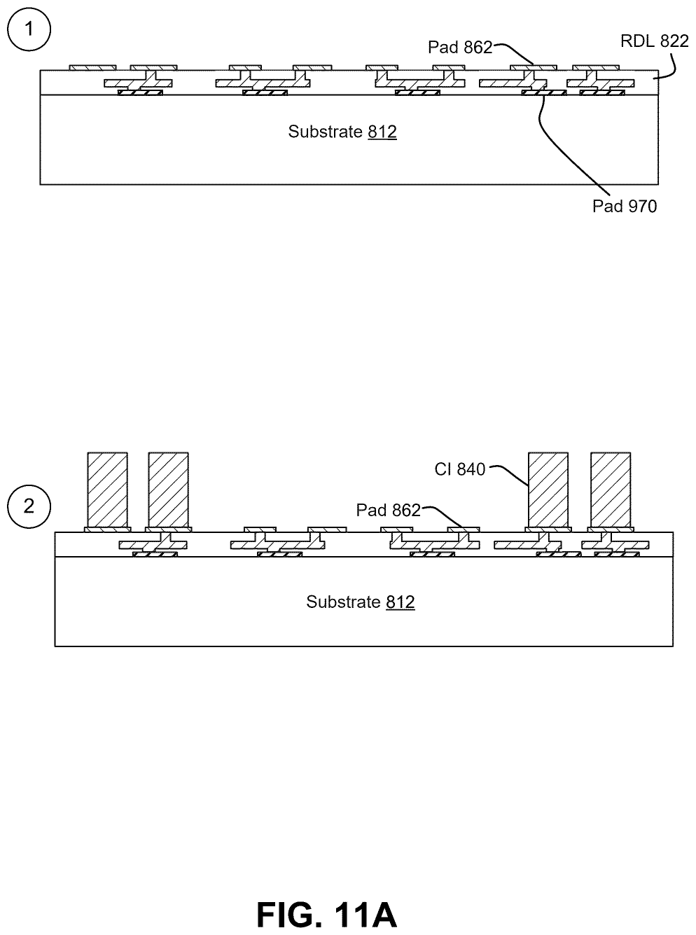

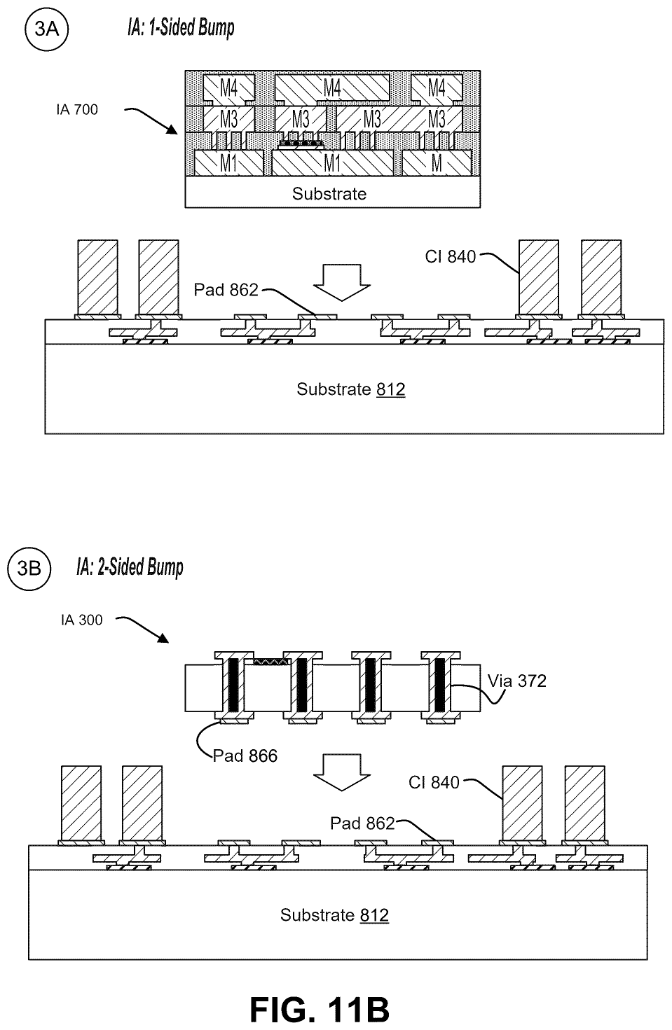

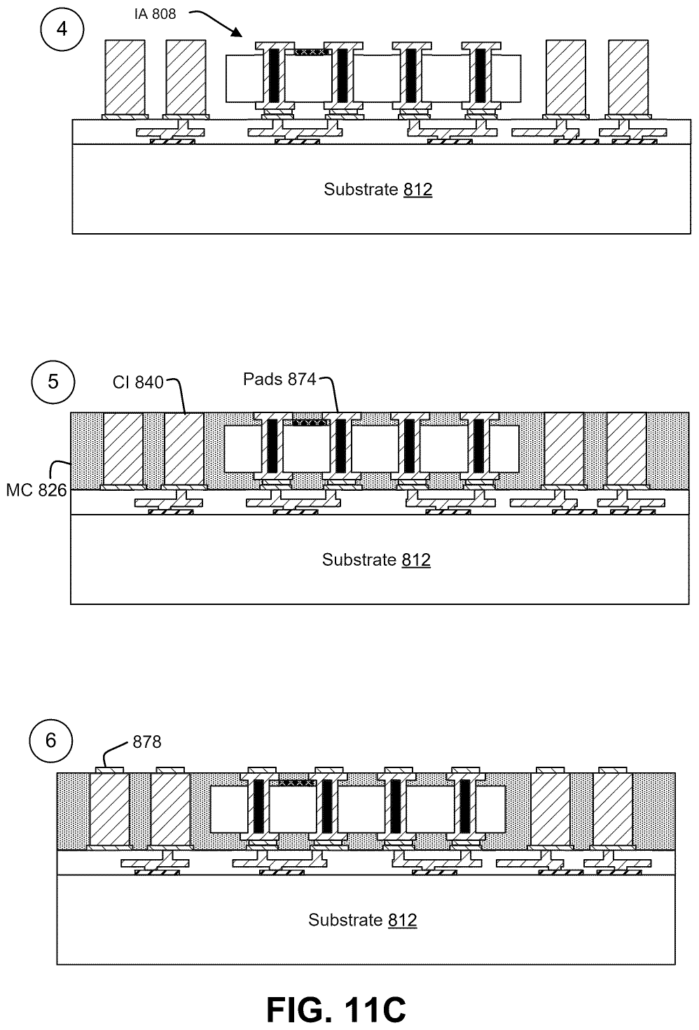

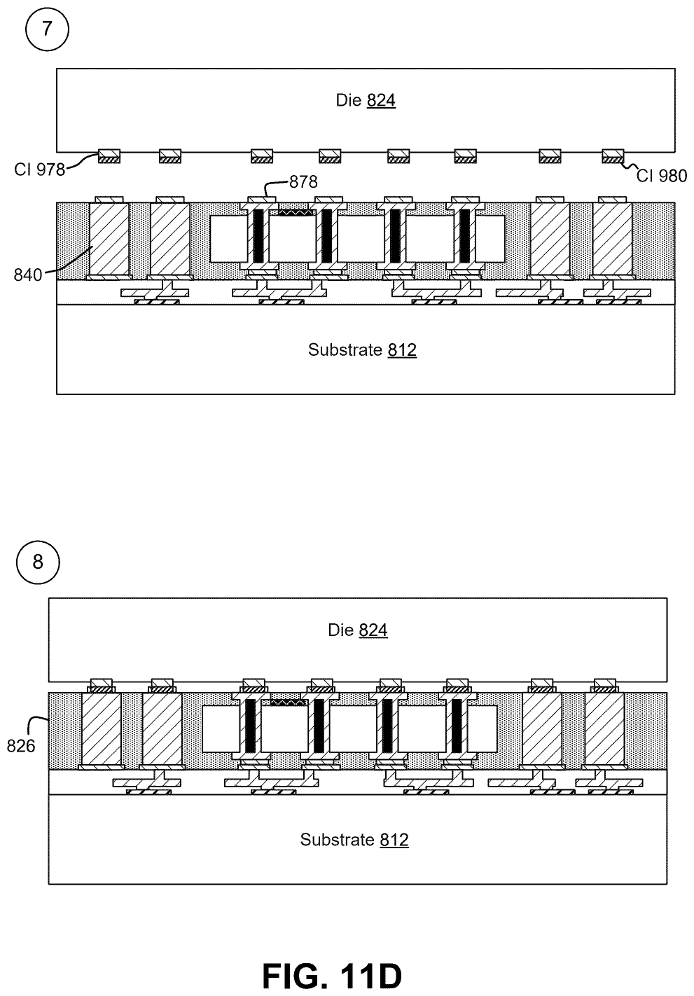

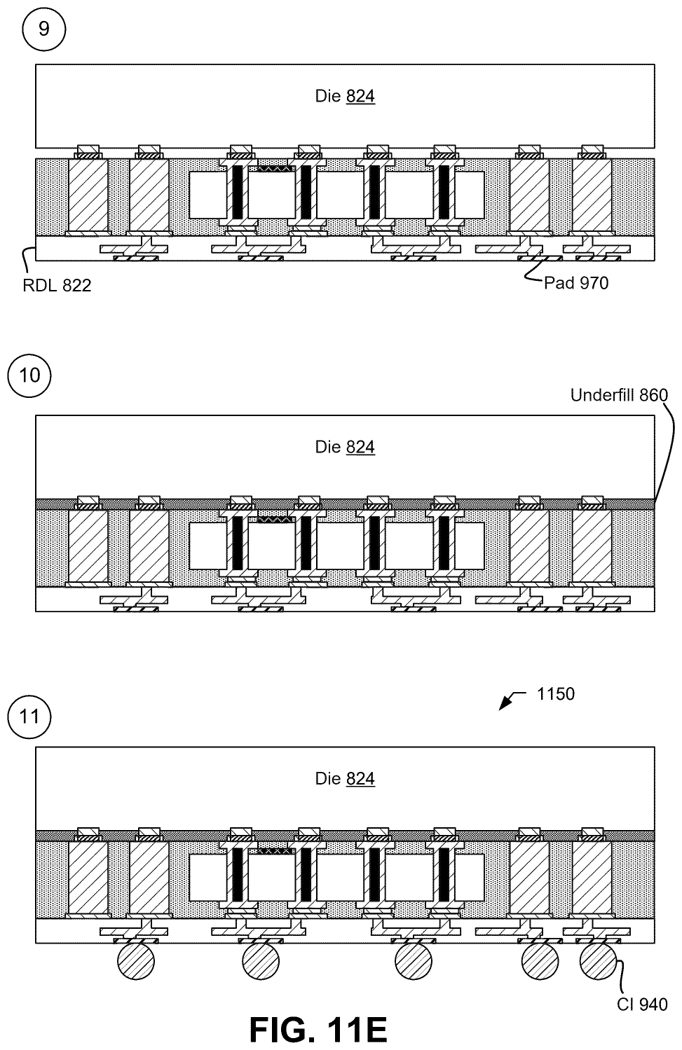

In some implementations, fabricating an IC device including an impedance adapter (e.g., any of the devices 150, 200, 250, 600, 800, 900, or 1050) includes several processes. FIGS. 11A-11E illustrate an exemplary sequence for providing or fabricating an IC device including at least one impedance adapter, as described with reference to any of FIGS. 1-10. In some implementations, the sequence of FIGS. 11A-11E may be used to provide (e.g., during fabrication of) one or more of the devices 150, 200, 250, 600, 800, 900, or 1050 of FIGS. 1, 2A, 2B, 6, 8-10.

It should be noted that the sequence of FIGS. 11A-11E may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 11A-11E.

Stage 1 of FIG. 11A illustrates a state after formation of metal layers (e.g., an RDL 822) on a substrate 812 (e.g., a glass panel carrier). The RDL 822 includes a set of alternating metal and dielectric layers. For example, the RDL 822 includes a first metal layer (e.g., one or more pads 970) electrically connected to a second metal layer (e.g., one or more pads 862). One or more plating processes, one or more deposition processes, and one or more patterning processes may be used to form the RDL 822. In a particular aspect, the RDL 822 corresponds to the RDL 122 of FIG. 1.

Stage 2 illustrates a state after forming conductors (e.g., conductive interconnects 840) on some of the pads 862. The conductive interconnects 840 can include electrical connectors (e.g., microbumps, conductive pads, or pillars) to form electrical connections via the pads 862 and the RDL 822 to the pads 970. One or more plating processes and one or more patterning processes may be used to form the conductive interconnects 840. In a particular embodiment, the conductive interconnects 840 correspond to copper pillars. In a particular aspect, the conductive interconnects 840 correspond to the conductive interconnects 136 of FIG. 1.

Stage 3A of FIG. 11B illustrates a state after aligning an impedance adapter 700 between a pair of conductive interconnects 840. In a particular aspect, the impedance adapter 808 of FIG. 8 corresponds to the impedance adapter 700. The impedance adapter 700 has one-sided bumps. In a particular aspect, there are no pads 862 disposed between the pair of conductive interconnects 840.

Stage 3B of FIG. 11B illustrates a state after aligning an impedance adapter 300 between a pair of conductive interconnects 840. The impedance adapter 300 has two-sided bumps. In a particular aspect, the impedance adapter 808 of FIG. 8 corresponds to the impedance adapter 300. Aligning the impedance adapter 300 can include aligning one or more vias 372, one or more pads 866, or a combination thereof, of the impedance adapter 300 to respective pads 862 that are between the pair of conductive interconnects 840. For example, the pads 862 are included in a metal layer (e.g., the RDL 822) of the substrate 812.

Stage 4 of FIG. 11C illustrates a state after attaching the impedance adapter 808. For example, one or more pads 866 of the impedance adapter 808 are attached to respective pads 862. In a particular implementation, die attach techniques are used to attach the impedance adapter 808. In an example, reflow of solder is used to form electrical connections between the pads 866 and the pads 862, and the solder is cured or hardened.

The impedance adapter 808 corresponding to the impedance adapter 300 that has two-sided bumps is provided as an illustrative example, in another example the impedance adapter 808 corresponds to the impedance adapter 700 that has one-sided bumps. In an example, a deposition process can be used to apply an adhesive (e.g., an epoxy or paste), the impedance adapter 700 can be placed on the adhesive, and the adhesive can be cured or hardened by exposure to light, heat, and/or chemical hardening agents.

In a particular aspect, multiple impedance adapters are attached. For example, an impedance adapter 108 and an impedance adapter 114 of FIG. 1 are attached.

Stage 5 illustrates a state after deposition of a mold compound 826 and application of a material removal process to expose a surface of the conductive interconnects 840 and a surface of the pads 874 of the impedance adapter 808. The material removal process can include grinding operations, patterning operations, etching processes, drilling operations, laser ablation operations, other targeted material removal operations, or combinations thereof.

Stage 6 illustrates a state after forming pads 878 (e.g., landing pads). For example first landing pads 878 are aligned with the conductive interconnects 840 and second landing pads 878 are aligned with the pads 874 and the vias 372. The pads 878 can include electrical connectors (e.g., microbumps, conductive pads, or pillars) to form electrical connections with the conductive interconnects 840 and the pads 874. One or more plating processes and one or more patterning processes may be used to form the pads 878.

Stage 7 of FIG. 11D illustrates a state after aligning a die 824. For example, conductive interconnects 978 are disposed in or on a surface of the die 824 and conductive interconnects 980 are disposed on the conductive interconnects 978. The conductive interconnects 980 are aligned with respective pads 878.

Stage 8 illustrates a state after attaching the die 824. For example, one or more conductive interconnects 980 are attached to respective pads 878 (e.g., copper pads) of the die 824. In a particular implementation, die attach techniques are used to couple first pads 878 of the die 824 via the conductive interconnects 980 to first pads 878 to electrically connect circuitry (e.g., RF circuitry) of the die 824 to the impedance adapter 808 and to couple second pads 878 of the die 824 via the conductive interconnects 840 to second pads 878 to electrically connect circuitry (e.g., RF circuitry) of the die 824 to metal layers (e.g., the RDL 822) of the substrate 812. In an example, a deposition process, a spin-on process, or a similar process can be used to apply an adhesive (e.g., an epoxy or paste) on the pads 878, the die 824 can be placed to have the conductive interconnects 980 on the adhesive, and the adhesive can be cured or hardened by exposure to light, heat, and/or chemical hardening agents. In an example, the pads 878 (e.g., solder paste) are reflowed to at least partially encapsulate the conductive interconnects 980 and cured or hardened.

In a particular aspect, one or more additional components (e.g., the low-noise amplifier(s) 112, the switch(es) 104, the power amplifier(s) 110, or a combination thereof) are attached. In a particular aspect, the die 824 is electrically connected to multiple impedance adapters. For example, the die 824 is electrically connected to an impedance adapter 108 and an impedance adapter 114 of FIG. 1. The die 824 is electrically connected to a first side of the impedance adapter 108 and a first side of the impedance adapter 114. The substrate 812 is on a second side of the impedance adapter 108 that is opposite the first side of the impedance adapter 108. The substrate 812 is on a second side of the impedance adapter 114 that is opposite the first side of the impedance adapter 114.

In a particular aspect, an underfill 860 is deposited between the die 824 and the mold compound 826 to form the device 800 of FIG. 8.

Stage 9 of FIG. 11E illustrates a state after removal of the substrate 812 to expose a surface of the pads 970 of the RDL 822. Stage 10 illustrates a state after depositing an underfill 860 between the die 824 and the mold compound 826. In a particular aspect, the underfill 860 includes epoxy, acrylic, urethane, or a combination thereof. In an example, a dispensing process is used to dispense a liquid underfill material in the gap between the die 824 and the mold compound 826, and the underfill material can be cured or hardened by exposure to light, heat, and/or chemical hardening agents to form the underfill 860.

Stage 11 illustrates a state after attaching conductive interconnects 940. For example, the conductive interconnects 940 can include electrical connectors (e.g., microbumps, conductive pads, or pillars) to form electrical connections with one or more other devices. One or more plating processes and one or more patterning processes may be used to form the conductive interconnects 940. In a particular embodiment, the conductive interconnects 940 correspond to solder bumps, e.g., a grid or array of solder bumps, formed on the pads 970 of the RDL 822. In a particular aspect, the conductive interconnects 940 correspond to the conductive interconnects 240 of FIG. 2B.

Formation of a device 1150 (e.g., a packaged IC device) is complete after Stage 11 of FIG. 11E. However, in some implementations, one or more similar operations can be performed to form one of the devices 150, 200, 250, 600, 800, 900, or 1050 of FIG. 1, 2A, 2B, 6, 8, 9, or 10.

### Exemplary Flow Diagram of a Method for Fabricating an Integrated Device Comprising Impedance Adapter

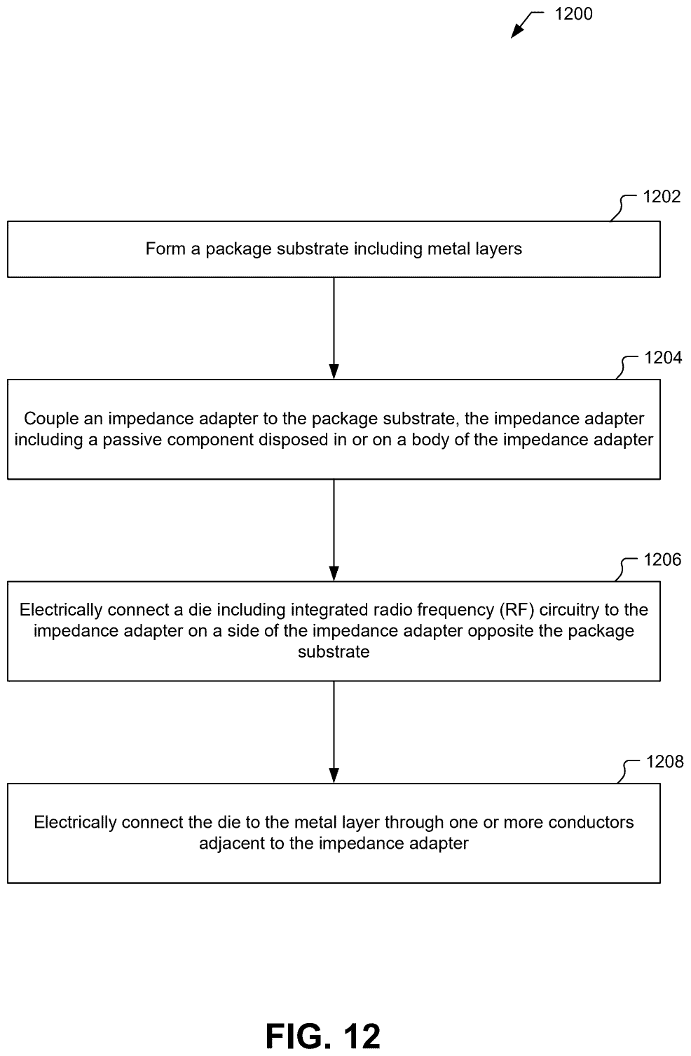

In some implementations, fabricating an IC device includes several processes. FIG. 12 illustrates an exemplary flow diagram of a method 1200 for providing or fabricating an IC device that includes an impedance adapter. In some implementations, the method 1200 of FIG. 12 may be used to provide or fabricate any of the IC devices 150, 200, 250, 600, 800, 900, 1050, or 1150 of FIG. 1, 2A, 2B, 6, 8, 9, 10, or 11E.

It should be noted that the method 1200 of FIG. 12 may combine one or more processes in order to simplify and/or clarify the method for providing or fabricating an integrated device. In some implementations, the order of the processes may be changed or modified.

The method 1200 includes, at block 1202, forming a package substrate including metal layers. For example, metal layers (e.g., the RDL 822, metal traces, or both) are formed in or on a substrate 812 (e.g., package substrate), as described with reference to Stage 1 of FIG. 11A.

The method 1200 also includes, at block 1204, coupling an impedance adapter to the package substrate, the impedance adapter including a passive component disposed in or on a body of the impedance adapter. For example, the impedance adapter 808 is coupled to the substrate 812 by attaching the pads 866 to the pads 862, as described with reference to Stage 4 of FIG. 11C. In another example, the impedance adapter 808 corresponds to the impedance adapter 700 of FIG. 7 and the substrate 308 of the impedance adapter 700 is attached to the pads 862, the RDL 822, or both.

The method 1200 further includes, at block 1206, electrically connecting a die including integrated radio frequency (RF) circuitry to the impedance adapter on a side of the impedance adapter opposite the package substrate. For example, the die 824 includes integrated RF circuitry and the die 824 is electrically connected to the impedance adapter 808 on a first side of the impedance adapter 808, the substrate 812 is on a second side of the impedance adapter 808, and the second side is opposite the first side, as described with reference to Stage 8 of FIG. 11D. To illustrate, a conductive path electrically connects the active circuitry of the die 824 to the impedance adapter 808. The conductive path includes a conductive interconnect 978, a conductive interconnect 980, a pad 878, and a via 838 of FIGS. 8-9.

The method 1200 also includes, at block 1208, electrically connecting the die to the metal layers through one or more conductors adjacent to the impedance adapter. For example, the die 824 is electrically connected to the metal layers (e.g., the RDL 822, metal traces, or both) through one or more conductive interconnects 840 that are adjacent to the impedance adapter 808, as described with reference to Stage 8 of FIG. 11D. For example, a first subset of the conductive interconnects 980 are electrically connected to a first subset of the pads 878 and the first subset of the pads 878 are disposed on the conductive interconnects 840 that are adjacent to the impedance adapter 808.

### Exemplary Electronic Devices

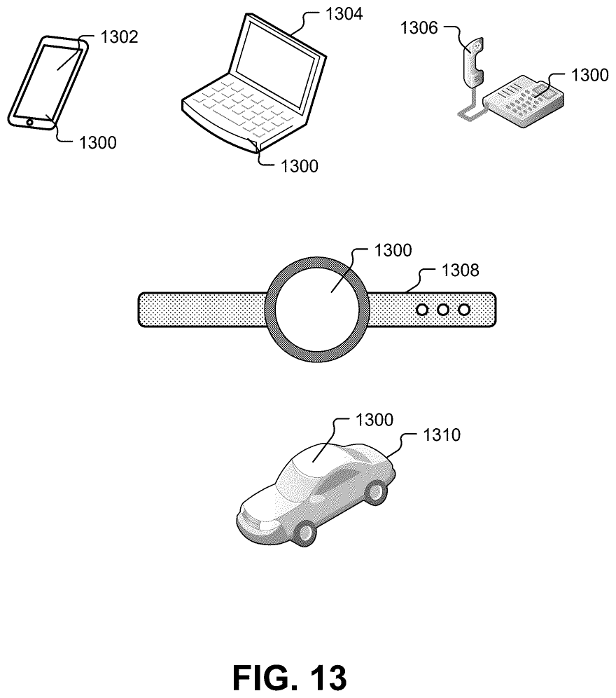

FIG. 13 illustrates various electronic devices that may include or be integrated with any of the IC devices 150, 200, 250, 600, 800, 900, 1050, or 1150. For example, a mobile phone device 1302, a laptop computer device 1304, a fixed location terminal device 1306, a wearable device 1308, or a vehicle 1310 (e.g., an automobile or an aerial device) may include a device 1300. The device 1300 can include, for example, any of the devices 150, 200, 250, 600, 800, 900, 1050, or 1150 described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-13 may be rearranged and/or combined into a single component, process, feature or function or embodied in several components, processes, or functions. Additional elements, components, processes, and/or functions may also be added without departing from the disclosure. It should also be noted FIGS. 1-13 and its corresponding description in the present disclosure is not limited to dies and/or ICs. In some implementations, FIGS. 1-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a packaged integrated circuit device includes: a die that includes integrated radio frequency (RF) circuitry; a package substrate including metal layers electrically connected to the RF circuitry; and an impedance adapter electrically connected to the RF circuitry and disposed between the die and the package substrate, the impedance adapter including a passive component disposed on or in a body of the impedance adapter.

Example 2 includes the packaged integrated circuit device of Example 1, and further includes one or more of a switch, a power amplifier (PA), or a low noise amplifier (LNA) electrically connected to the metal layers and disposed adjacent to the die.

Example 3 includes the packaged integrated circuit device of Example 1 or Example 2, wherein the impedance adapter also includes one or more active components.

Example 4 includes the packaged integrated circuit device of Example 3, wherein the one or more active components include at least one of an amplifier, a filter, a power amplifier (PA), or a low noise amplifier (LNA).

Example 5 includes the packaged integrated circuit device of any of Examples 1 to 4, wherein the passive component includes one or more inductors.

Example 6 includes the packaged integrated circuit device of any of Examples 1 to 5, wherein the passive component includes at least one two-dimensional (2D) inductor disposed on a surface of the body of the impedance adapter.

Example 7 includes the packaged integrated circuit device of any of Examples 1 to 6, wherein the passive component includes a three-dimensional (3D) inductor including interconnected through vias defining a solenoid, the through vias extending through the body of the impedance adapter.

Example 8 includes the packaged integrated circuit device of any of Examples 1 to 7, wherein the passive component include a varactor.

Example 9 includes the packaged integrated circuit device of any of Examples 1 to 8, wherein the passive component includes a metal-insulator-metal (MIM) capacitor.

Example 10 includes the packaged integrated circuit device of any of Examples 1 to 9, and further includes conductive vias through the passive component, the conductive vias electrically connected to the RF circuitry and the metal layers.

Example 11 includes the packaged integrated circuit device of any of Examples 1 to 10, and further includes a second impedance adapter disposed between the die and the package substrate.

Example 12 includes the packaged integrated circuit device of any of Examples 1 to 11, and further includes conductive interconnects electrically connected to the RF circuitry and the metal layers.

Example 13 includes the packaged integrated circuit device of any of Examples 1 to 12, and further includes solder balls disposed on a first side of the package substrate, wherein the impedance adapter is disposed on a second side of the package substrate that is opposite the first side.

Example 14 includes the packaged integrated circuit device of any of Examples 1 to 13, wherein the die includes a complementary metal oxide semiconductor (CMOS) RF die.

According to Example 15, a method of fabrication includes: forming a package substrate including metal layers; coupling an impedance adapter to the package substrate, the impedance adapter including a passive component disposed in or on a body of the impedance adapter; electrically connecting a die including integrated radio frequency (RF) circuitry to the impedance adapter on a side of the impedance adapter opposite the package substrate; and electrically connecting the die to the metal layers through one or more conductors adjacent to the impedance adapter.

Example 16 includes the method of Example 15, wherein the passive component includes conductive vias, wherein the metal layers include landing pads, and wherein coupling the impedance adapter to the package substrate includes aligning the conductive vias with the landing pads.

Example 17 includes the method of Example 15 or 16, and further includes forming the conductors on the package substrate.

Example 18 includes the method of any of Examples 15 to 17, and further includes forming landing pads including first landing pads aligned with the conductors and second landing pads aligned with conductive vias of the passive component.

Example 19 includes the method of Example 18, and further includes coupling first copper pads of the die to the first landing pads to electrically connect the RF circuitry to the metal layers.

Example 20 includes the method of Example 18 or Example 19, and further includes coupling second copper pads of the die to the second landing pads to electrically connect the RF circuitry to the impedance adapter.

Example 21 includes the method of any of Examples 15 to 20, wherein the impedance adapter also includes one or more active components.

Example 22 includes the method of Example 21, wherein the one or more active components include at least one of an amplifier, a filter, a power amplifier (PA), or a low noise amplifier (LNA).

Example 23 includes the method of any of Examples 15 to 22, wherein the passive component includes one or more inductors.

Example 24 includes the method of any of Examples 15 to 23, wherein the passive component includes at least one two-dimensional (2D) inductor disposed on a surface of the body of the impedance adapter.

Example 25 includes the method of any of Examples 15 to 24, wherein the passive component includes a three-dimensional (3D) inductor including interconnected through vias defining a solenoid, the through vias extending through the body of the impedance adapter.

Example 26 includes the method of any of Examples 15 to 25, wherein the passive component includes a varactor.

Example 27 includes the method of any of Examples 15 to 26, wherein the passive component includes a metal-insulator-metal (MIM) capacitor.

Example 28 includes the method of any of Examples 15 to 27, and further includes: coupling a second impedance adapter to the package substrate; and electrically connecting the die to the second impedance adapter on a side of the second impedance adapter opposite the package substrate.

According to Example 29, a packaged integrated circuit device includes: a die that includes integrated radio frequency (RF) circuitry; a package substrate including metal layers electrically connected to the RF circuitry; a first impedance adapter electrically connected to the RF circuitry and disposed between the die and the package substrate; and a second impedance adapter electrically connected to the RF circuitry and disposed between the die and the package substrate.

Example 30 includes the packaged integrated circuit device of Example 29, wherein the first impedance adapter includes a varactor and the second impedance adapter includes a metal-insulator-metal (MIM) capacitor.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A packaged integrated circuit device comprising:
a die that includes integrated radio frequency (RF) circuitry;
a package substrate including metal layers electrically connected to the RF circuitry; and
an impedance adapter electrically connected to the RF circuitry and disposed between the die and the package substrate, the impedance adapter including a passive component disposed on or in a body of the impedance adapter.

2. The packaged integrated circuit device of claim 1, further comprising one or more of a switch, a power amplifier (PA), or a low noise amplifier (LNA) electrically connected to the metal layers and disposed adjacent to the die.

3. The packaged integrated circuit device of claim 1, wherein the impedance adapter also includes one or more active components.

4. The packaged integrated circuit device of claim 3, wherein the one or more active components include at least one of an amplifier, a filter, a power amplifier (PA), or a low noise amplifier (LNA).

5. The packaged integrated circuit device of claim 1, wherein the passive component includes one or more inductors.

6. The packaged integrated circuit device of claim 1, wherein the passive component includes at least one two-dimensional (2D) inductor disposed on a surface of the body of the impedance adapter.

7. The packaged integrated circuit device of claim 1, wherein the passive component includes a three-dimensional (3D) inductor including interconnected through vias defining a solenoid, the through vias extending through the body of the impedance adapter.

8. The packaged integrated circuit device of claim 1, wherein the passive component include a varactor.

9. The packaged integrated circuit device of claim 1, wherein the passive component includes a metal-insulator-metal (MIM) capacitor.

10. The packaged integrated circuit device of claim 1, further comprising conductive vias through the passive component, the conductive vias electrically connected to the RF circuitry and the metal layers.

11. The packaged integrated circuit device of claim 1, further comprising a second impedance adapter disposed between the die and the package substrate.

12. The packaged integrated circuit device of claim 1, further comprising conductive interconnects electrically connected to the RF circuitry and the metal layers.

13. The packaged integrated circuit device of claim 1, further comprising solder balls disposed on a first side of the package substrate, wherein the impedance adapter is disposed on a second side of the package substrate that is opposite the first side.

14. The packaged integrated circuit device of claim 1, wherein the die includes a complementary metal oxide semiconductor (CMOS) RF die.

15. A method of fabrication comprising:
forming a package substrate including metal layers;
coupling an impedance adapter to the package substrate, the impedance adapter including a passive component disposed in or on a body of the impedance adapter;
electrically connecting a die including integrated radio frequency (RF) circuitry to the impedance adapter on a side of the impedance adapter opposite the package substrate; and
electrically connecting the die to the metal layers through one or more conductors adjacent to the impedance adapter.

16. The method of claim 15, wherein the passive component includes conductive vias, wherein the metal layers include landing pads, and wherein coupling the impedance adapter to the package substrate includes aligning the conductive vias with the landing pads.

17. The method of claim 15, further comprising forming the conductors on the package substrate.

18. The method of claim 17, further comprising forming landing pads including first landing pads aligned with the conductors and second landing pads aligned with conductive vias of the passive component.

19. The method of claim 18, further comprising coupling first copper pads of the die to the first landing pads to electrically connect the RF circuitry to the metal layers.

20. The method of claim 18, further comprising coupling second copper pads of the die to the second landing pads to electrically connect the RF circuitry to the impedance adapter.

21. The method of claim 15, wherein the impedance adapter also includes one or more active components.

22. The method of claim 21, wherein the one or more active components include at least one of an amplifier, a filter, a power amplifier (PA), or a low noise amplifier (LNA).

23. The method of claim 15, wherein the passive component includes one or more inductors.

24. The method of claim 15, wherein the passive component includes at least one two-dimensional (2D) inductor disposed on a surface of the body of the impedance adapter.

25. The method of claim 15, wherein the passive component includes a three-dimensional (3D) inductor including interconnected through vias defining a solenoid, the through vias extending through the body of the impedance adapter.

26. The method of claim 15, wherein the passive component includes a varactor.

27. The method of claim 15, wherein the passive component includes a metal-insulator-metal (MIM) capacitor.

28. The method of claim 15, further comprising:
coupling a second impedance adapter to the package substrate; and
electrically connecting the die to the second impedance adapter on a side of the second impedance adapter opposite the package substrate.

29. A packaged integrated circuit device comprising:
a die that includes integrated radio frequency (RF) circuitry;
a package substrate including metal layers electrically connected to the RF circuitry;
a first impedance adapter electrically connected to the RF circuitry and disposed between the die and the package substrate; and
a second impedance adapter electrically connected to the RF circuitry and disposed between the die and the package substrate.

30. The packaged integrated circuit device of claim 29, wherein the first impedance adapter includes a varactor and the second impedance adapter includes a metal-insulator-metal (MIM) capacitor.
